(19) United States
(12) Patent Application Publication
(10) Pub. No.: US 2022/0238394 A1
(43) Pub. Date: Jul. 28, 2022

(54) TEMPERATURE CONTROL METHOD, TEMPERATURE CONTROL DEVICE, AND OPTICAL HEATING DEVICE

(71) Applicant: Ushio Denki Kabushiki Kaisha, Tokyo (JP)

(72) Inventors: Shinji Taniguchi, Tokyo (JP); Takahiro Inoue, Tokyo (JP); Takafumi Mizojiri, Tokyo (JP)

(73) Assignee: Ushio Denki Kabushiki Kaisha, Tokyo (JP)

(21) Appl. No.: 17/578,973

(22) Filed: Jan. 19, 2022

(30) Foreign Application Priority Data
Jan. 22, 2021 (JP) 2021-008588

(51) Int. Cl. H01L 21/66; H01L 21/67; H01L 21/324

(52) U.S. Cl. CPC H01L 22/20; H01L 21/67248; H01L 22/12; H01L 21/67115; H01L 21/324

(57) ABSTRACT

A method includes a step (A) of causing the light source part to repeatedly switch between a light-on state and a substantially light-off state, a step (B) of measuring the temperature of the substrate to be treated by observing infrared light radiated from the substrate to be treated while the light source part is kept in the substantially light-off state in the step (A), and a step (C) of determining either of a level of electricity supplied to the light source part in a next round of the light-on state and a time for which the light source part is kept in the next round of the light-on state based on the temperature of the substrate to be treated measured in the step (B) and a predetermined target temperature.

### TECHNICAL FIELD

The present invention relates to a temperature control method, a temperature control device, and an optical heating device.

### BACKGROUND ART

In a semiconductor manufacturing process, various heat treatments such as a film formation treatment, an oxidation and diffusion treatment, a reforming treatment, and an annealing treatment are performed on a substrate to be treated such as a semiconductor wafer. In these treatments, a heat treatment method using photoirradiation is often employed to enable noncontact treatment. Patent Document 1 described below discloses an optical heating device that includes a light-emitting diode (LED) as a light source for heating, for example.

### CITATION LIST

### Patent Document

Patent Document 1: JP-A-2020-009927

### SUMMARY OF INVENTION

Heat treatment in semiconductor manufacturing processes, or more specifically, factors such as a temperature and time maintained for heat treatment and a rate at which the temperature goes up or down, influence the quality of manufactured semiconductor devices. Thus, a heat treatment process for the substrate to be treated is required to be controlled such that a temperature of the substrate to be treated reaches and converges to a target temperature quickly and accurately.

For instance, Patent Document 1 discloses a method of controlling a temperature of a semiconductor wafer, a substrate to be treated, by measuring the temperature of the semiconductor wafer with a temperature measurement instrument of a noncontact-type such as a thermograph and concurrently controlling an electric current supplied to the LED in response to the temperature of the semiconductor wafer measured with the temperature measurement instrument.

Although the temperature of the semiconductor wafer is controlled by the temperature control method as described above so as to reach a predetermined target temperature, the temperature of the semiconductor wafer, in some cases, converges to a temperature different from the target temperature or is slow in converging to the target temperature.

In view of the above problem, it is an object of the present invention to provide a temperature control method, a temperature control device, and an optical heating device that enable a temperature of a substrate to be treated with heat through photoirradiation to be measured and controlled with increased accuracy.

### Solution to Problem

A temperature control method according to the present invention is a method of controlling a temperature of a substrate to be treated with heat using light emitted from a light source part including a plurality of solid-state light sources. The method includes:

a step (A) of causing the light source part to repeatedly switch between a light-on state and a substantially light-off state;

a step (B) of measuring the temperature of the substrate to be treated by observing infrared light radiated from the substrate to be treated while the light source part is kept in the substantially light-off state in the step (A); and

a step (C) of determining either of a level of electricity supplied to the light source part in a next round of the light-on state and a time for which the light source part is kept in the next round of the light-on state based on the temperature of the substrate to be treated measured in the step (B) and a predetermined target temperature.

The “substantially light-off state” used in this specification means a state in which the light source part is turned off as well as a state in which radiance of the solid-state light sources of the light source part in a measurement wavelength range of a radiation thermometer is as low as less than or equal to 3 mW/sr/m² to avoid occurrence of an error in measuring the temperature of the substrate to be treated in the step (B).

The “predetermined target temperature” is, for example, a temperature that the substrate to be treated reaches for heat treatment and a reference temperature at which control processes are switched.

The inventors of the present invention have extensively studied and found that the temperature control method described above cannot successfully enable the measurement and control of the temperature of the substrate to be treated owing to factors described below.

Controlling the temperature of the substrate to be treated by measuring the temperature of the substrate to be treated and concurrently controlling the electric current supplied to the LED in response to the measured temperature of the substrate to be treated means that light is always emitted by a light source part toward the substrate to be treated when the temperature is measured.

Even if the light is light in a wavelength range different from a sensitive wavelength range that is a range of wavelengths of light the measurement instrument such as the thermograph observes to measure temperatures, the light contains light, albeit slightly, of wavelengths within the sensitive wavelength range for the measurement instrument such as the thermograph. Hence, such a temperature measurement instrument, which is designed to measure temperatures by receiving infrared light radiated from an object to be measured, inevitably receives part of light emitted from the light source and transmitted though the semiconductor wafer and light traveling after being reflected off an inner wall surface of a chamber together with the light radiated from the semiconductor wafer.

In other words, because of an error occurring between the measured temperature of the substrate to be treated and an actual temperature of the substrate to be treated due to a quantity, an intensity, and other properties of unnecessary light the measurement instrument receives together with the light radiated from the substrate to be treated, the temperature of the substrate to be treated cannot be successfully controlled.

In view of the factors described above, possible methods for measuring and controlling the temperature of the substrate to be treated with increased accuracy are temperature control methods as described below. Conceivably, a temperature control method, for example involves keeping the light source part in a light-on state until the temperature of the substrate to be treated reaches a target temperature, causing the light source part to switch to a light-off state to measure the temperature of the substrate to be treated when the temperature of the substrate to be treated exceeds the target temperature, and causing the light source part to switch again to the light-on state when the temperature falls below the target temperature.

However, with the method, the light source part does not switch to the light-off state and thus a time when the temperature of the substrate to be treated is checked does not come until attainment of the target temperature is confirmed. It is conceivable that the light source part can switch to the light-off state at a predetermined time to measure the temperature of the substrate to be treated. However, it is not realistic to specify appropriate timing on every occasion in response to an output status of the light source part and a size of the substrate to be treated or a material from which the substrate is made.

Conceivably, another method for temperature control involves a temperature control method of changing a duty cycle based on a difference between the measured temperature of the substrate to be treated and the target temperature under lighting control of the light source part whereby the light source part repeatedly switches between the light-on state and the light-off state in a certain cycle.

However, with the control method, a very short period of the light-off state may take place, and in some cases, the light source part may be controlled so as to be always kept in the light-on state. In other words, with the control method, in the same way as the above control method, a temperature control device can possibly get into a state in which a time when the temperature of the substrate to be treated is checked does not come.

To address this problem, the method described above ensures that the temperature of the substrate to be treated is measured while the light source part is in the light-off state. Thus, the quantity and intensity of light emitted from the light source part and incident on a light-receiving area of a thermometer are reduced compared to cases where the temperature of the substrate to be treated is measured while the light source part is in the light-on state. This reduces an error between the actual temperature of the substrate to be treated with heat and the temperature measured with the thermometer.

With the method described above, the light source part switches between the light-on state and the light-off state irrespective of whether the temperature of the substrate to be treated has reached the target temperature and thus a time when the thermometer can measure the temperature of the substrate to be treated without being affected by light emitted from the light source part comes.

In the temperature control method described above, the step (C) may include controlling the level of the electricity supplied to the light source part in the next round of the light-on state by a proportional control based on a difference between the temperature of the substrate to be treated measured in the step (B) and the target temperature and by an integral control based on a change in the temperature of the substrate to be treated measured in the step (B) over time.

In the temperature control method described above, the step (C) may include controlling the level of the electricity supplied to the light source part in the next round of the light-on state by the proportional control based on a difference between the temperature of the substrate to be treated measured in the step (B) and the target temperature and by the integral control and a derivative control based on a change in the temperature of the substrate to be treated measured in the step (B) over time.

The level of the supplied electric power is less susceptible to a driving capacity of a power supply device and a parasitic capacity of connected wires than timing with which the supply and cut-off of the electric power are switched. Thus, controlling the level of the electricity helps control the temperature of the substrate to be treated with improved precision.

Accordingly, with the method described above, the temperature of the substrate to be treated rises efficiently to the target temperature owing to control by the proportional operation (termed “proportional control” or “P control”). At the same time, an offset against the target temperature, which cannot be reduced by only the proportional control, is reduced owing to control by the integral operation (termed “integral control” or “I control”). The method of control combining proportional control and integral control in this way is generally termed PI control.

Further, the method includes controlling the level of the electricity by the derivative operation (termed “derivative control” or “D control”) and thus suppresses a sudden change in temperature of the substrate to be treated caused by external perturbations and other factors. The method of control combining proportional control, integral control, and derivative control is generally termed PID control.

With the method of control described above, the temperature of the substrate to be treated rises by converging to the target temperature with improved quickness and immediately returns to the target temperature in response to the occurrence of an abrupt change in temperature of the substrate to be treated caused by external perturbations and other factors.

In the temperature control method described above, the temperature of the substrate to be treated may be measured with a radiation thermometer in the step (B).

The radiation thermometer displays quick response compared to thermal cameras and other instruments. Thus, the time for which the light source part is kept in the light-off state that is set in the step (A) can be shorten. The radiation thermometer provides high accuracy in temperature measurement compared to thermal cameras and other instruments. Thus, with the method described above, the radiation thermometer helps measure and control the temperature of the substrate to be treated with increased accuracy without a decrease in heating efficiency.

A temperature control device according to the present invention is a device for controlling a temperature of a substrate to be treated with heat. The device includes:

a light source part including a plurality of solid-state light sources to emit light toward the substrate to be treated;

a controller to control the device to cause the light source part to repeatedly switch between a light-on state and a substantially light-off state; and

a thermometer to measure the temperature of the substrate to be treated by receiving infrared light radiated from the substrate to be treated while the light source part is in the substantially light-off state under control of the controller,

wherein the controller is configured to determine either of a level of electricity supplied to the light source part in a next round of the light-on state and a time for which the light source part is kept in the next round of the light-on state based on the temperature of the substrate to be treated measured with the thermometer and a predetermined target temperature.

In the temperature control device described above, the controller may be configured to control the level of the electricity supplied to the light source part in the next round of the light-on state by a proportional control based on a difference between the temperature of the substrate to be treated measured with the thermometer and the target temperature and by an integral control based on a change in the temperature of the substrate to be treated measured with the thermometer over time.

In the temperature control device described above, the controller may be configured to control the level of the electricity supplied to the light source part in the next round of the light-on state by the proportional control based on a difference between the temperature of the substrate to be treated measured with the thermometer and the target temperature and by the integral control and a derivative control based on a change in the temperature of the substrate to be treated measured with the thermometer over time.

In the temperature control device described above, the thermometer may be a radiation thermometer.

An optical heating device according to the present invention includes:

the temperature control device described above;

a chamber to house the substrate to be treated; and

a supporter inside the chamber to support the substrate to be treated.

With the above configuration, the temperature of the substrate to be treated is measured while the light source part is in the light-off state. Thus, the quantity and intensity of light emitted from the light source part and incident on a light-receiving area of a thermometer are reduced compared to cases where the temperature of the substrate to be treated is measured while the light source part is in the light-on state. This reduces an error between the actual temperature of the substrate to be treated with heat and the temperature measured with the thermometer.

With the above configuration, the light source part switches between the light-on state and the light-off state irrespective of whether the temperature of the substrate to be treated has reached the target temperature and thus a time when temperature measurement is allowed comes. Further, the time for which the light source part is kept in the light-off state is not controlled depending on the temperature of the substrate to be treated and thus, under control action, is not controlled to such an extent that temperature measurement cannot be completed.

The present invention can implement a temperature control method, a temperature control device, and an optical heating device that enable a temperature of a substrate to be treated with heat through photoirradiation to be measured and controlled with increased accuracy.

### BRIEF DESCRIPTION OF THE DRAWINGS

FIG. 1A is a schematic cross-sectional view of a configuration of an optical heating device according to an embodiment, viewed along a Y direction;

FIG. 1B is a plan view of a chamber in FIG. 1A, viewed from +Z side;

FIG. 1C is a schematic cross-sectional view of a configuration of an optical heating device according to an embodiment, viewed along the Y direction;

FIG. 2 is a schematic block diagram showing a configuration of a controller;

FIG. 3 shows graphs of an example showing how the controller controls an electric current supplied to a light source part and a measurement trigger signal;

FIG. 4 is a graph showing a result of verification in Example 1;

FIG. 5 is a graph showing a result of verification in Comparative Example 1;

FIG. 6 shows graphs of an example showing how the controller controls an electric current supplied to a light source part and a measurement trigger signal;

FIG. 7 shows graphs of an example showing how the controller controls an electric current supplied to a light source part and a measurement trigger signal; and

FIG. 8 shows graphs of an example showing how the controller controls an electric current supplied to a light source part and a measurement trigger signal.

### DETAILED DESCRIPTION OF THE PREFERRED EMBODIMENTS

A temperature control method, a temperature control device, and an optical heating device of the present invention will now be described with reference to the attached drawings. All the drawings shown below regarding a temperature control device and an optical heating device are schematic views, and the size proportion and the number of components on each drawing do not necessarily coincide with an actual proportion and number.

### [Optical Heating Device]

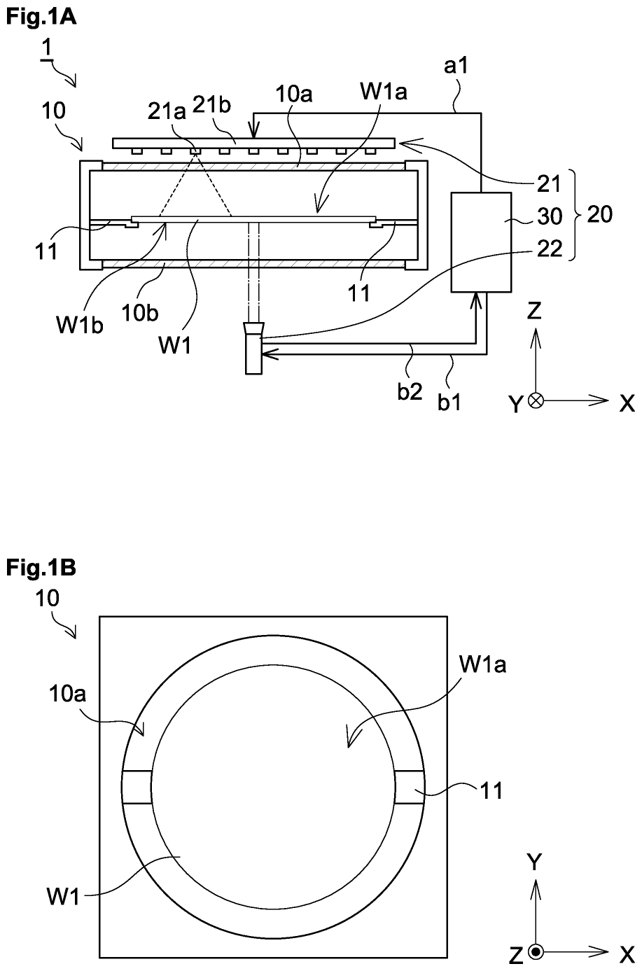

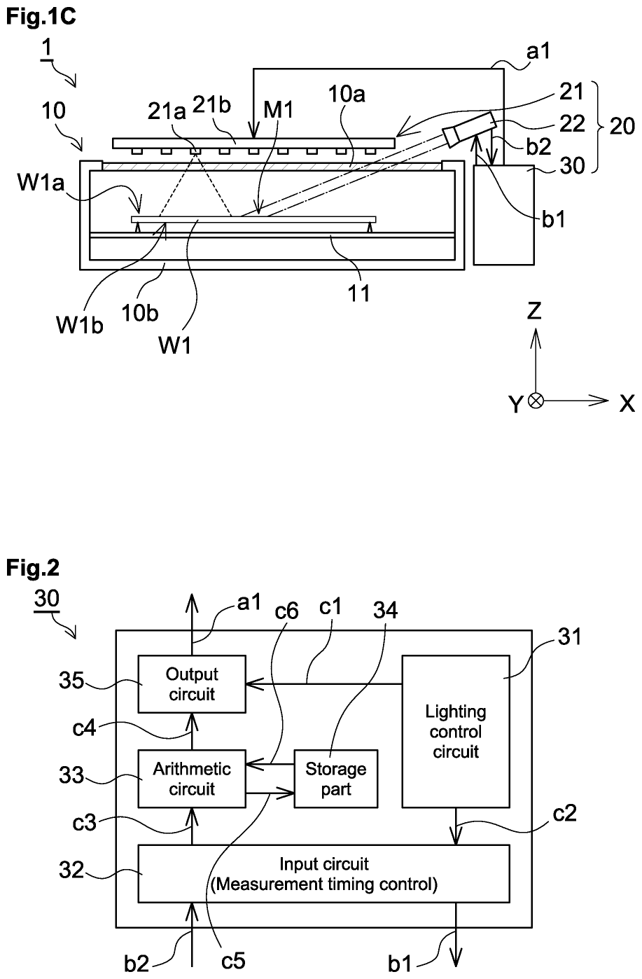

First, a configuration of an optical heating device 1 will be described. FIG. 1A is a schematic cross-sectional view of the configuration of the optical heating device 1 according to an embodiment, viewed along a Y direction. FIG. 1B is a plan view of a chamber 10 in FIG. 1A, viewed from +Z side. As shown in FIG. 1A, the optical heating device 1 of a first embodiment includes the chamber 10 to house a substrate to be treated W1 and a temperature control device 20. The temperature control device 20 includes a light source part 21, a radiation thermometer 22, and a controller 30.

The present embodiment is described on the assumption that the substrate to be treated W1 is a silicon wafer. However, the substrate to be treated may be a semiconductor wafer made of a material other than silicon or may be a substrate such as a glass substrate. The substrate to be treated W1 has a first principal surface W1a on which a pattern (not shown) is formed and a second principal surface W1b on which no pattern is formed, such that the principal surfaces are distinguished from each other. The same applies to the substrate to be treated W1 that is a semiconductor wafer made of a material other than silicon or that is a glass substrate.

In the description given below, as shown in FIGS. 1A and 1B, a direction in which a light-emitting diode (LED) substrate 21b and the substrate to be treated W1 face each other is defined as a Z direction, a direction in which a pair of supporters 11 described later are opposed to each other is an X direction, and a direction orthogonal to both the X direction and the Z direction is a Y direction.

When positive and negative sides are distinguished from each other in representing a direction, a plus or minus sign is added as in “+Z direction” and “−Z direction. For representing a direction without distinction between positive and negative sides, a direction like “Z direction” is simply written.

The chamber 10, as shown in FIGS. 1A and 1B, includes the pair of supporters 11 to support the substrate to be treated W1, a light-transmissive window 10a to allow light emitted from the light source part 21 to come inward, and an observation window 10b to allow the radiation thermometer 22 to measure a temperature of the second principal surface W1b of the substrate to be treated W1. In FIG. 1B, an area where the light-transmissive window 10a is formed is not hatched such that an inner configuration of the chamber 10 can be observed.

As shown in FIG. 1A, the light source part 21 includes a plurality of LED elements 21a on the LED substrate 21b and is disposed so as to emit light toward the first principal surface W1a of the substrate to be treated W1 supported by the supporter 11. A solid-state light source included in the light source part 21 may be another light source such as a laser diode (LD), a fluorescent light source, or a combination of these light sources. In the present embodiment, the LED elements 21a emit light that has a peak intensity at a wavelength of 405 nm. However, the light emitted by the light source part 21 may be light that has a spectral peak in any of wavelength ranges of ultraviolet light, visible light, infrared light, and other radiation, with proviso that the light has a heating effect on the substrate to be treated W1.

The light-transmissive window 10a is a window through which at least the light emitted from the LED elements 21a is transmitted. The observation window 10b is a window through which infrared light is transmitted and observed by the radiation thermometer 22. The light-transmissive window 10a and the observation window 10b are not necessarily windows that display transparency to all beams of light emitted from the LED elements 21a and all beams of light in a sensitive wavelength range for the radiation thermometer 22, respectively, with proviso that heat treatment for the substrate to be treated W1 and measurement by the radiation thermometer 22 are performed without problems.

FIG. 1C is a schematic cross-sectional view of a configuration of an embodiment different from the optical heating device 1 of FIG. 1A, viewed along the Y direction. Whereas the radiation thermometer 22 in the present embodiment, as shown in FIG. 1A, is disposed so as to measure the temperature of the second principal surface W1b of the substrate to be treated W1, a radiation thermometer 22 may be disposed, as shown in FIG. 1C, so as to measure a temperature of a first principal surface W1a of a substrate to be treated W1. As shown in FIG. 1C, a light source part 21 and the radiation thermometer 22 may be disposed on the same side relative to the substrate to be treated W1, and the radiation thermometer 22 may be disposed so as to measure the temperature of the substrate to be treated W1 through infrared light radiated in a direction leaning from the Z direction.

The controller 30, as shown in FIG. 1A, supplies an electric current al to the light source part 21 and outputs a measurement trigger signal b1 to the radiation thermometer 22 to control timing with which the substrate temperature is measured. The controller 30 receives an electric signal b2 based on the measured temperature of the substrate to be treated W1 from the radiation thermometer 22.

FIG. 2 is a schematic block diagram showing a configuration of the controller 30. As shown in FIG. 2, the controller 30 includes a lighting control circuit 31, an input circuit 32, an arithmetic circuit 33, a storage part 34, and an output circuit 35.

The lighting control circuit 31 outputs a lighting control signal c1 to the output circuit 35 to switch between a light-on state and a light-off state and outputs a sync signal c2 to the input circuit 32 to synchronize a time when the radiation thermometer 22 measures the temperature of the substrate to be treated W1 with the light-on state and the light-off state.

In response to the sync signal c2 input from the lighting control circuit 31, the input circuit 32 generates the measurement trigger signal b1 to control the timing when the temperature of the substrate to be treated W1 is measured and outputs the measurement trigger signal b1 to the radiation thermometer 22. The input circuit 32 receives the electric signal b2, which contains information on the measured temperature of the substrate to be treated W1, from the radiation thermometer 22, converts the electric signal b2 into arithmetical temperature data c3 that can be processed by the arithmetic circuit 33, and outputs the arithmetical temperature data c3 to the arithmetic circuit 33.

Upon receiving the arithmetical temperature data c3 output from the input circuit 32, the arithmetic circuit 33 generates storage-purpose temperature data c5 from the arithmetical temperature data c3 and stores the storage-purpose temperature data c5 in the storage part 34.

The arithmetic circuit 33 reads out comparison-purpose temperature data c6 stored in the storage part 34 and performs a proportional operation, an integral operation, and a derivative operation based on a change in temperature of the substrate to be treated W1 over time in reference to the arithmetical temperature data c3 and the comparison-purpose temperature data c6 (the three operations are hereinafter collectively abbreviated as a “PID operation” except that the operations are each individually described). Based on an operation result determined by the PID operation, the arithmetic circuit 33 generates a current value signal c4 that contains information on a current value supplied to the light source part 21 and that can be processed by the output circuit 35 and outputs the current value signal c4 to the output circuit 35.

In the present embodiment, the comparison-purpose temperature data c6 is data containing target temperature data used to treat the substrate to be treated W1 with heat and temperature data stored previously.

Upon receiving the lighting control signal c1 that is output from the lighting control circuit 31 and that causes the light source part to switch to the light-on state, the output circuit 35 supplies the electric current al of a current value based on the current value signal c4 to the light source part 21.

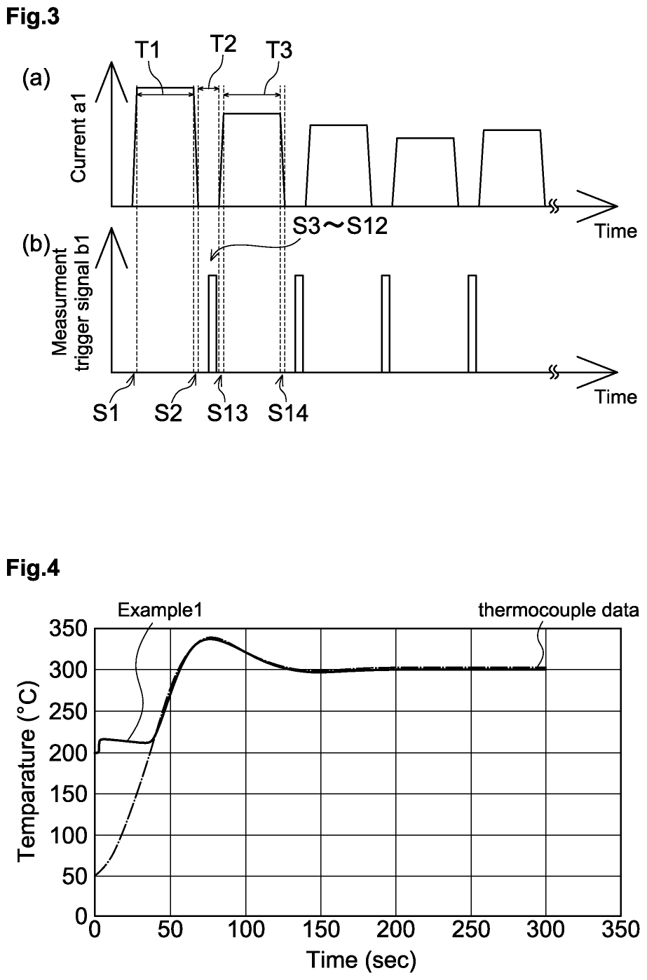

FIG. 3 shows graphs of an example showing how the controller 30 controls the electric current al supplied to the light source part 21 and the measurement trigger signal b1. The graph (a) is an enlarged view showing a part of a waveform of the electric current al immediately after control start, and the graph (b) is an enlarged view showing a part of a waveform of the measurement trigger signal b1 immediately after control start.

With reference to FIG. 3, a temperature control method provided by the temperature control device 20 will now be described based on the configuration of the optical heating device 1.

When the substrate to be treated W1, as shown in FIGS. 1A and 1B is disposed inside the chamber 10 so as to be supported by the supporter 11, the controller 30 starts supplying the electric current al to the light source part 21 (step S1).

As shown in FIG. 3, after supplying the electric current al to the light source part 21 throughout a predetermined time interval T1, the controller 30 stops supplying the electric current al to the light source part 21 (step S2). The time interval T1 is equivalent to a time for which the light source part 21 is kept in the light-on state.

After stopping the supply of the electric current al to the light source part 21, the controller 30 outputs the measurement trigger signal b1 to the radiation thermometer 22 to start temperature measurement (step S3).

In response to an input of the measurement trigger signal b1, the radiation thermometer 22 measures the temperature of the second principal surface W1b of the substrate to be treated W1 (step S4). Since the supply of the electric current al to the light source part 21 stops in step S2 and step S14 described later, step S4 is executed while the light source part is in the light-off state. This step S4 corresponds to a step (B).

Upon completing the measurement of the temperature of the substrate to be treated W1, the radiation thermometer 22 outputs the electric signal b2 to the controller 30 (step S5). The electric signal b2 is input into the controller 30 and is input as-is into the input circuit 32.

The input circuit 32 converts the electric signal b2, which is input from the radiation thermometer 22, into the arithmetical temperature data c3 and outputs the arithmetical temperature data c3 to the arithmetic circuit 33 (step S6).

Upon receiving the arithmetical temperature data c3 from the input circuit 32, the arithmetic circuit 33 generates the storage-purpose temperature data c5 based on the arithmetical temperature data c3 to store the storage-purpose temperature data in the storage part 34 and stores the storage-purpose temperature data c5 in the storage part 34 (step S7).

Upon receiving the arithmetical temperature data c3 from the input circuit 32, the arithmetic circuit 33 reads out the comparison-purpose temperature data c6, which is stored in advance, from the storage part 34 (step S8).

Upon reading out the comparison-purpose temperature data c6 from the storage part 34, the arithmetic circuit 33 performs a proportional operation based on a difference between the arithmetical temperature data c3 containing information about the temperature of the substrate to be treated W1 measured with the thermometer and the target temperature data contained in the comparison-purpose temperature data c6 read out from the storage part 34 (step S9).

Upon reading out the comparison-purpose temperature data c6 from the storage part 34, the arithmetic circuit 33 also performs an integral operation and a derivative operation based on a change in temperature of the substrate to be treated W1 over time in reference to the arithmetical temperature data c3 containing information about the temperature of the substrate to be treated W1 measured with the thermometer and previously stored temperature data contained in the comparison-purpose temperature data c6 read out from the storage part 34 (step S10). Step S9 and step S10 correspond to a step (C).

In cases such as a time of first measurement where the previously stored storage-purpose temperature data c5 is not present, the integral operation and the derivative operation may not be performed. In step S10, only the proportional operation and the integral operation may be performed without the derivative operation.

Based on data determined by the PID operation, the arithmetic circuit 33 generates the current value signal c4 that contains information on a current value supplied to the light source part 21 and that can be processed by the output circuit 35 and outputs the current value signal c4 to the output circuit 35 (step S11).

The output circuit 35 prepares to output the electric current al of a current value based on the current value signal c4 and waits for an input of the lighting control signal c1 that is output from the lighting control circuit 31 and that causes the light source part to switch to the light-on state (step S12).

As shown in FIG. 3, a time interval T2 for which the supply of the electric current al to the light source part 21 is stopped is equivalent to a time for which the light source part 21 is kept in the light-off state. During the time interval T2, steps S3 to S12 are executed. In other words, the temperature of the substrate to be treated W1 is measured by the radiation thermometer 22 while the light source part 21 is kept in the light-off state. The time interval T2 is preferably, for example, within a range of 0.001 second or more and 2 seconds or less, and more preferably within a range of 0.01 second or more and 1 second or less, and even more preferably within a range of 0.05 second and 0.5 second. If the time interval T2 is too short, the thermometer may be affected by the light emitted from the light source and the temperature may not be measured accurately, so the time interval T2 should be somewhat longer.

At a time when the output circuit 35 receives the lighting control signal c1 that is output from the lighting control circuit 31 and that causes the light source part to switch to the light-on state, the output circuit 35 starts supplying the electric current al of a current value based on the current value signal c4 to the light source part 21 (step S13).

After continuing supplying the electric current al to the light source part 21 throughout a predetermined time interval T3, the output circuit 35 stops supplying the electric current al to the light source part 21 at a time when the output circuit receives the lighting control signal c1 from the lighting control circuit 31 (step S14). The time interval T3 is equivalent to a time for which the light source part 21 is kept in the light-on state. After that, steps S3 to S14 are repeated.

By repetition of steps S3 to S14, the light source part 21 repeatedly switches between the light-on state and the light-off state. Based on feedback about the temperature value measured with the radiation thermometer 22, PID control is executed on the current value of the supplied electric current al. In this way, the temperature of the substrate to be treated W1 is controlled to converge to a target temperature. An action of the light source part 21 repeatedly switching between the light-on state and the light-off state by repetition of steps S3 to S14 corresponds to a step (A).

### [Verification]

Experimental verification was conducted with the optical heating device 1 to check an error occurring when the temperature of the substrate to be treated W1 was measured by the radiation thermometer 22 with the light source part kept in the light-on state and an effect of the error on control over the temperature of the substrate to be treated W1. This experimental verification was conducted with the optical heating device 1 having the configuration shown in FIG. 1C.

### Example 1

A case in which the temperature of the substrate to be treated W1 was measured and controlled using the temperature control method described above is referred to as Example 1.

### Comparative Example 1

A case in which the temperature of the substrate to be treated W1 was measured and controlled using the same method as in Example 1 except that measurement and control were conducted with the light source part 21 kept in the light-on state without stopping the supply of the electric current al to the light source part 21 is referred to as Comparative Example 1.

### Experimental Method

The light source part 21 was disposed such that the substrate to be treated W1 and a light-emitting surface of each LED element 21a were separated by a distance of 75 mm.

A time for which the light source part was kept in the light-on state was 1,050 milliseconds, and a time for which the light source part was kept in the light-off state was 50 milliseconds.

The radiation thermometer 22 used was the FLHX-PNE0220-0300B005-000 radiation thermometer made by Japan Sensor Corporation. Main characteristics of the product are shown below:

Sensitive wavelength range: 0.8 μm to 1.6 μm

Measuring range: 220° C. to 1650° C.

The substrate to be treated W1 and the radiation thermometer 22 were separated by a distance of 300 mm.

A target temperature to be reached was 300 degrees. A verification time was 300 seconds from control start.

In both Example 1 and Comparative Example 1, the temperature of the substrate to be treated W1 was measured with a thermocouple attached to the second principal surface W1b of the substrate to be treated W1 concurrently with the radiation thermometer 22 to check an actual temperature of the substrate to be treated W1 under control action. A place to which the thermocouple was attached, as shown in FIG. 1C, was on a side opposite to a zone M1, which was measured with the radiation thermometer 22 and in the first principal surface W1a of the substrate to be treated W1.

### (Results)

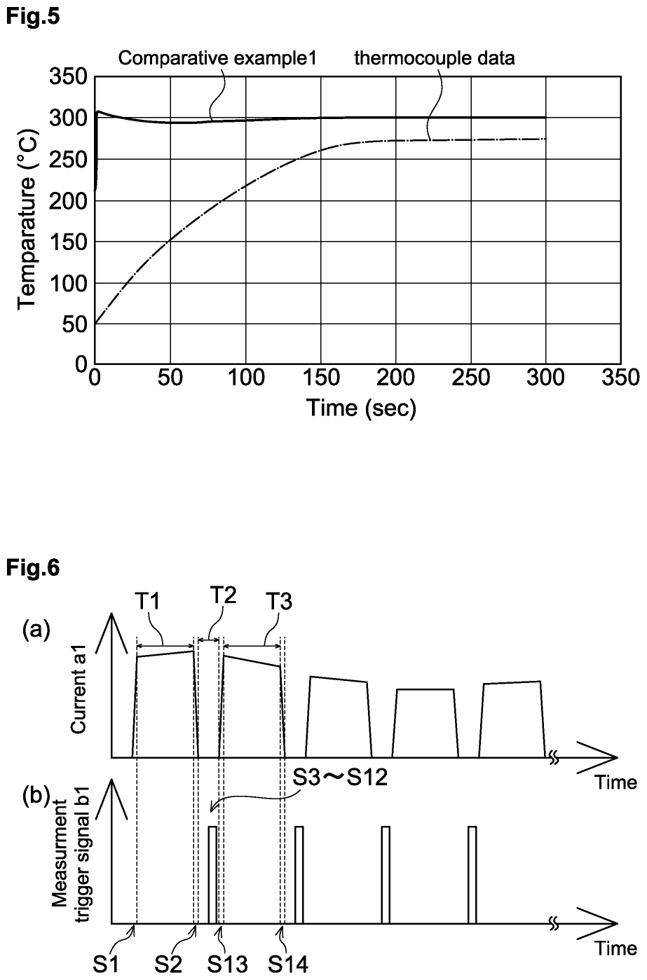

FIG. 4 is a graph showing a result of verification in Example 1, and FIG. 5 is a graph showing a result of verification in Comparative Example 1. In Example 1, as shown in FIG. 4, the temperature of the substrate to be treated W1 is measured with the radiation thermometer 22 so that substantially coincide with data acquired with the thermocouple after a neighborhood of 40 seconds when the temperature reaches 220 degrees or higher, a measuring range of the radiation thermometer 22, following control start. The temperature converges to the target temperature 300 degrees.

In Comparative Example 1, as shown in FIG. 5, the temperature value measured with the radiation thermometer 22, immediately after control start, changes to higher than or equal to the target temperature 300 degrees to be reached. Conceivably, this is because the radiation thermometer 22, immediately after control start, receives a part of light emitted from the light source part 21 and transmitted through the substrate to be treated W1.

By the control method of Comparative Example 1, as shown in FIG. 5, the temperature measured with the radiation thermometer 22 reaches 300 degrees immediately after control start, and thus the controller 30 falsely recognizes that the temperature of the substrate to be treated W1 has reached a neighborhood of the target temperature immediately after control start. Hence, although the temperature of the substrate to be treated W1 has not reached 300 degrees, the controller 30 controls the output circuit so as to supply the light source part 21 with a minimum level of the electric current al required for maintaining the temperature of the substrate to be treated W1 at 300 degrees.

Thus, the light source part 21 is unable to emit light necessary for increasing the temperature of the substrate to be treated W1 to the target temperature immediately after control start and afterward. As a result, as shown in FIG. 5, the temperature of the substrate to be treated W1 does not readily rise and does not reach the target temperature after all.

Consequently, with the configuration and the method described above, the light source part 21 is in the light-off state at a time when the temperature of the second principal surface W1b of the substrate to be treated W1 is measured. The radiation thermometer 22 receiving light radiated from the substrate to be treated W1 scarcely receives light emitted from the light source part 21. This reduces an error between the temperature of the substrate to be treated W1 that is under heat treatment and that is measured with the radiation thermometer 22 and the actual temperature of the substrate to be treated W1, and thus the temperature of the substrate to be treated W1 converges to the target temperature quickly and accurately.

The light source part 21 switches between the light-on state and the light-off state irrespective of whether the temperature of the substrate to be treated W1 has reached the target temperature and thus a time when the radiation thermometer 22 can measure the temperature of the substrate to be treated W1 without being affected by light emitted from the light source part 21 comes. Further, the time for which the light source part 21 is kept in the light-off state is not controlled depending on the temperature of the substrate to be treated W1 and thus, under control action, is not controlled to such an extent that measurement of the temperature of the substrate to be treated W1 cannot be completed.

In the present embodiment, the radiation thermometer is used as a thermometer to measure the temperature of the substrate to be treated W1. However, another thermometer may be used, with proviso that the thermometer is able to measure temperatures in a noncontacting manner by observing infrared light in accordance with requirements including the measuring temperature range and the time for which the light-off state is kept. Such a thermometer is, for example, a thermal camera.

In the present embodiment, the light source part 21, as shown in FIG. 1A, is disposed so as to emit light toward the first principal surface W1a of the substrate to be treated W1. However, the light source part may be disposed so as to emit light toward the second principal surface W1b of the substrate to be treated W1.

In the present embodiment, the arithmetic circuit 33 included in the controller 30 is configured to perform the PID operation and execute PID control on the current value of the electric current al supplied to the light source part 21. However, the arithmetic circuit may be configured to execute any feedback control other than PID control. For instance, the feedback control may be control executed to switch current values of the electric current al supplied to the light source part 21 depending on whether the temperature measured with the thermometer is higher or lower than the target temperature to be reached by the temperature of the substrate to be treated W1.

The chamber 10 in the present embodiment, as shown in FIG. 1A, has the light-transmissive window 10a and the observation window 10b. If the light source part 21 and the radiation thermometer 22 are housed inside the chamber 10, the chamber 10 may not be provided with the light-transmissive window 10a and the observation window 10b.

The supporter 11 supporting the substrate to be treated W1 may have any structure with proviso that the first principal surface W1a is disposed on an XY-plane. As shown in FIG. 1C, a supporter 11 may have, for example, a plurality of pin-shaped protrusions whereby the substrate to be treated W1 is supported at their tips.

FIG. 6 shows graphs of an example, which is different from those in FIG. 3, showing how the controller 30 controls the current value of the electric current supplied to the light source part 21. The electric current al shown in FIG. 3 is constant when the light source part is in the light-on state. However, as shown in FIG. 6, the current value of the electric current al supplied to the light source part 21 during a time such as the time interval T1 and the time interval T3 may change over time. The current value of electric current al at time interval T3 may be controlled by PID control based on the temperature measured at time interval T2.

### OTHER EMBODIMENTS

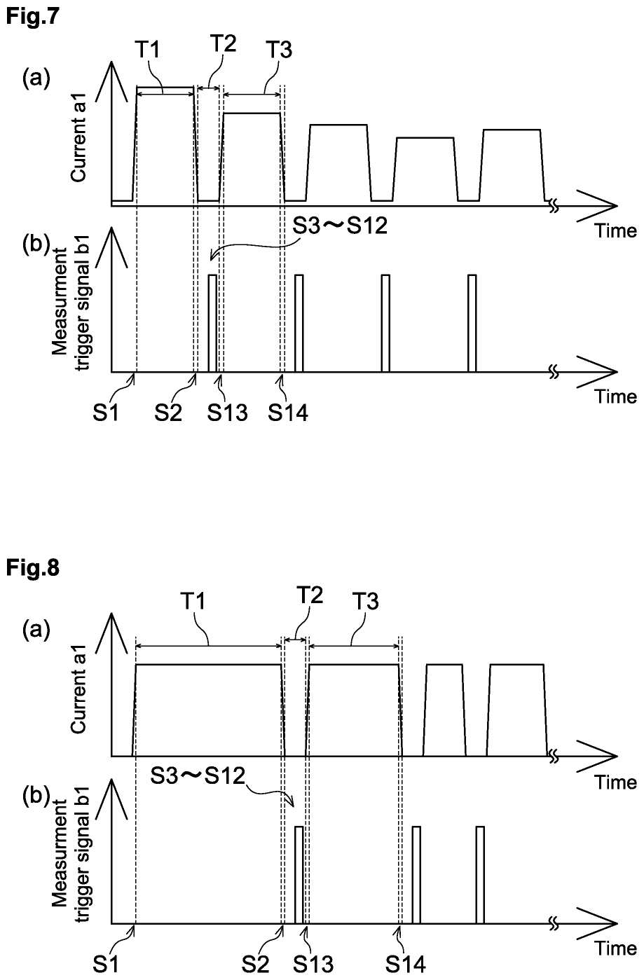

Other embodiments will now be described.

<1> FIG. 7 shows graphs of an example, which is different from that in FIGS. 3 and 6, showing how the controller 30 controls the current value of the electric current al supplied to the light source part 21. The graph (a) is an enlarged view showing a part of a waveform of the electric current al immediately after control start, and the graph (b) is an enlarged view showing a part of a waveform of the measurement trigger signal b1 immediately after control start. The electric current al supplied to the light source part 21 is not necessarily fully stopped during the time interval T2 as shown in FIG. 3. The electric current al that is very low in intensity may be kept supplied during the time interval T2 so that the light source part 21 continues emitting feeble light as shown in FIG. 7.

Under such control, the supply of the electric current al to the light source part 21 is not stopped and the light source part 21 is not turned off even in the light-off state. Hence, with the control described above, a time taken until the light source part 21 starts emitting light in response to resupply of the electric current al to the light source part 21 is shorter, albeit slightly, compared to the case in which the supply of the electric current al is stopped and the light source part 21 is turned off. This helps improve efficiency with which the substrate to be treated W1 is heated.

In the present embodiment, the current value of the electric current al supplied to the light source part 21 during the time interval T2 is adjusted to meet the light-off state condition described above such that, during the time interval T2, radiance of the LED elements 21a in a measurement wavelength range of the radiation thermometer (e.g., a wavelength range from 0.8 μm to 1.6 μm when the radiation thermometer used in the above verification is used) is less than or equal to 3 mW/sr/m².

<2> FIG. 8 shows graphs of an example, which is different from those in FIGS. 3, 6 and 7, showing how the controller 30 controls the current value of the electric current al supplied to the light source part 21. The graph (a) is an enlarged view showing a part of a waveform of the electric current al immediately after control start, and the graph (b) is an enlarged view showing a part of a waveform of the measurement trigger signal b1 immediately after control start. As shown in FIG. 8, the temperature of the substrate to be treated W1 may be controlled such that the time for which the light source part 21 is kept in the light-on state varies.

<3> The configurations of the optical heating device 1 and the temperature control device 20 described above are merely examples, and the illustrated configurations should not be construed to limit the present invention.

What is claimed is:

1. A temperature control method of controlling a temperature of a substrate to be treated with heat using light emitted from a light source part including a plurality of solid-state light sources, the method comprising:
a step (A) of causing the light source part to repeatedly switch between a light-on state and a substantially light-off state;
a step (B) of measuring the temperature of the substrate to be treated by observing infrared light radiated from the substrate to be treated while the light source part is kept in the substantially light-off state in the step (A); and
a step (C) of determining either of a level of electricity supplied to the light source part in a next round of the light-on state and a time for which the light source part is kept in the next round of the light-on state based on the temperature of the substrate to be treated measured in the step (B) and a predetermined target temperature.

2. The temperature control method according to claim 1, wherein the step (C) includes controlling the level of the electricity supplied to the light source part in the next round of the light-on state by a proportional control based on a difference between the temperature of the substrate to be treated measured in the step (B) and the target temperature and by an integral control based on a change in the temperature of the substrate to be treated measured in the step (B) over time.

3. The temperature control method according to claim 2, wherein the step (C) includes controlling the level of the electricity supplied to the light source part in the next round of the light-on state by the proportional control based on a difference between the temperature of the substrate to be treated measured in the step (B) and the target temperature and by the integral control and a derivative control based on a change in the temperature of the substrate to be treated measured in the step (B) over time.

4. The temperature control method according to claim 1, wherein the temperature of the substrate to be treated is measured with a radiation thermometer in the step (B).

5. A temperature control device for controlling a temperature of a substrate to be treated with heat, the device comprising:
a light source part including a plurality of solid-state light sources to emit light toward the substrate to be treated;
a controller to control the device to cause the light source part to repeatedly switch between a light-on state and a substantially light-off state; and
a thermometer to measure the temperature of the substrate to be treated by receiving infrared light radiated from the substrate to be treated while the light source part is in the substantially light-off state under control of the controller,
wherein the controller is configured to determine either of a level of electricity supplied to the light source part in a next round of the light-on state and a time for which the light source part is kept in the next round of the light-on state based on the temperature of the substrate to be treated measured with the thermometer and a predetermined target temperature.

6. The temperature control device according to claim 5, wherein the controller is configured to control the level of the electricity supplied to the light source part in the next round of the light-on state by a proportional control based on a difference between the temperature of the substrate to be treated measured with the thermometer and the target temperature and by an integral control based on a change in the temperature of the substrate to be treated measured with the thermometer over time.

7. The temperature control device according to claim 6, wherein the controller is configured to control the level of the electricity supplied to the light source part in the next round of the light-on state by the proportional control based on a difference between the temperature of the substrate to be treated measured with the thermometer and the target temperature and by the integral control and a derivative control based on a change in the temperature of the substrate to be treated measured with the thermometer over time.

8. The temperature control device according to claim 5, wherein the thermometer is a radiation thermometer.

9. An optical heating device comprising:
the temperature control device according to claim 5;
a chamber to house the substrate to be treated; and
a supporter inside the chamber to support the substrate to be treated.
